(19) United States
(12) Patent Application Publication
(10) Pub. No.: US 2026/0026338 A1
(43) Pub. Date: Jan. 22, 2026

(54) SEMICONDUCTOR STRUCTURE AND MANUFACTURING METHOD THEREOF

(71) Applicant: Taiwan Semiconductor Manufacturing Company, Ltd., Hsinchu (TW)

(72) Inventors: Ting-Ya LO, Hsinchu (TW); HSU-WEI LIU, Hsinchu (TW); Cheng-Chin LEE, Hsinchu (TW); Shao-Kuan LEE, Hsinchu (TW); Hsin-Yen HUANG, Hsinchu (TW); Hsiao-Kang CHANG, Hsinchu (TW)

(73) Assignee: Taiwan Semiconductor Manufacturing Company, Ltd., Hsinchu (TW)

(21) Appl. No.: 18/779,394

(22) Filed: Jul. 22, 2024

(51) Int. Cl. H01L 21/768; H01L 23/522; H01L 23/528; H01L 23/532

(52) U.S. Cl. CPC H01L 21/7682; H01L 21/76814; H01L 21/76816; H01L 23/5222; H01L 23/5228; H01L 23/5283; H01L 23/5328

(57) ABSTRACT

A semiconductor structure and a manufacturing method thereof are provided. The manufacturing method of the semiconductor structure includes: forming a sacrificial layer in a concave in a metal layer; recessing the sacrificial layer; filling a metal-organic framework layer in the concave; and removing the sacrificial layer to form an air gap in the concave.

### BACKGROUND

The disclosure relates in general to a semiconductor structure and a manufacturing method thereof, and more particularly to a semiconductor structure with metal organic framework layer and air gap and a manufacturing method thereof.

Critical dimension, as well as pitch, continues to scale down for new tech nodes. Hence, there are more challenges on keeping lower resistivity (Rs) and preventing low-k material from etch damage during patterning. Consequently, for next-generation interconnect development, one of the key challenges will be to achieve low metal resistivity (Rs) and low dielectric capacitance (C) simultaneously.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a semiconductor structure according to one embodiment of the present disclosure.

FIGS. 2A to 2B show a flowchart of a manufacturing method of the semiconductor structure according to one embodiment of the present disclosure.

FIGS. 3 to 13 illustrate steps in the manufacturing method described in the FIGS. 2A to 2B.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “comprise,” “comprising,” “include,” “including,” “has,” “having,” etc. used in this specification are open-ended and mean “comprises but not limited.” The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

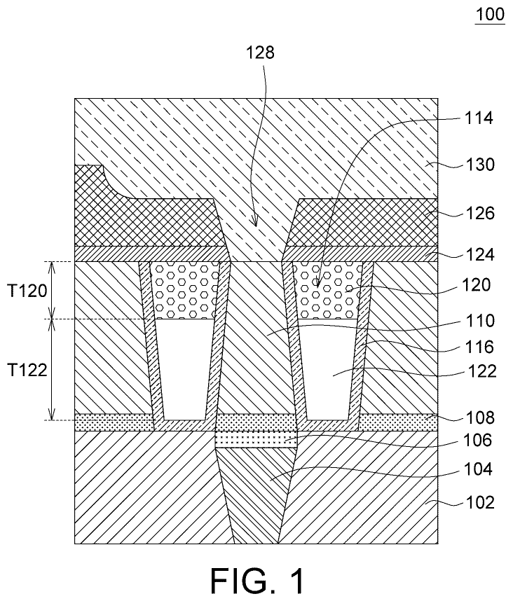

Please refer to FIG. 1, which shows a semiconductor structure 100 according to one embodiment of the present disclosure. The semiconductor structure 100 is, for example, a back end of line (BEOL) structure. In the semiconductor structure 100, a contact layer 104, a metal layer 110 and a conductive layer 130 are stacked and electrically connected. In the present embodiment, a metal-organic framework layer 120 and an air gap 122 are formed in at least one concave 114 to reduce the capacitance.

The metal-organic framework layer 120 has a plurality of holes. Some of the hoes are connected with each other. Air is filled in the holes, so that the capacitance could be reduced. A material of the metal-organic framework layer 120 is Zn, Sr, Pb, Mn, Co or Pb based organic network crystal. The metal-organic framework layer 120 occupies 20% to 50% of the concave 114. For example, a thickness T120 of the metal-organic framework layer 120 is 50 Å to 700 Å.

The air gap 122 is disposed between the metal-organic framework layer 120 and the bottom of the concave 114. The air gap 122 occupies 50% to 80% of the concave 114. For example, a thickness T122 of the air gap 122 is 10 Å to 100 Å.

In the embodiment, the metal-organic framework layer 120 and the air gap 122 are formed after forming and etching the metal layer 110, so the metal-organic framework layer 120 and the air gap 122 could be kept well without etching damage.

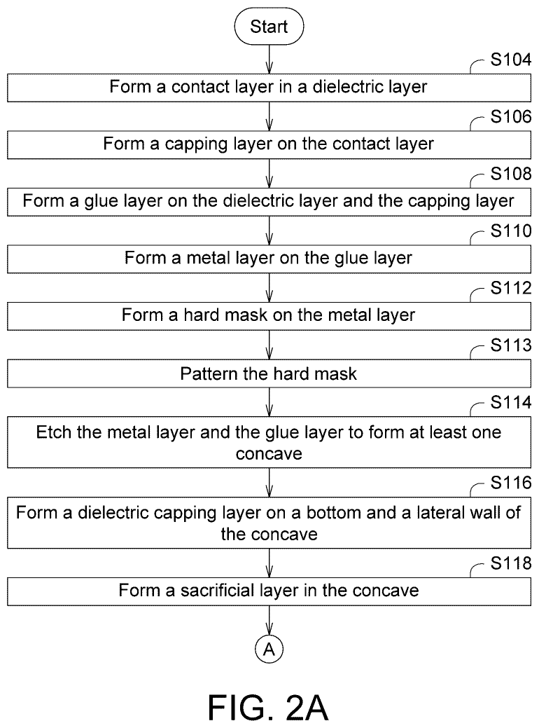

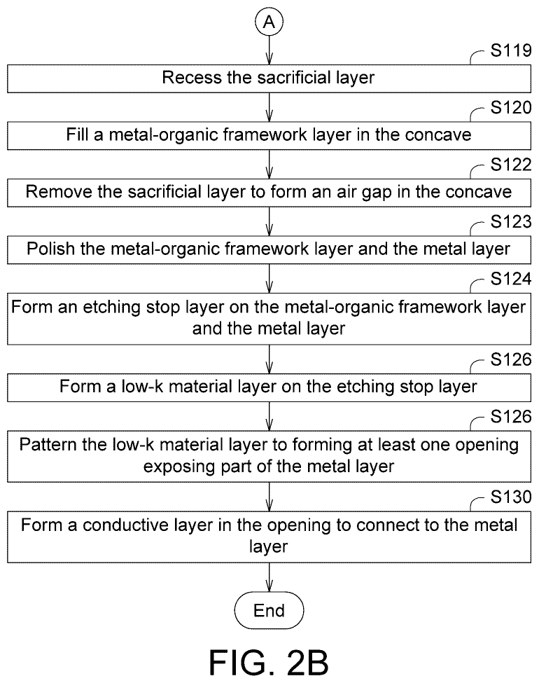

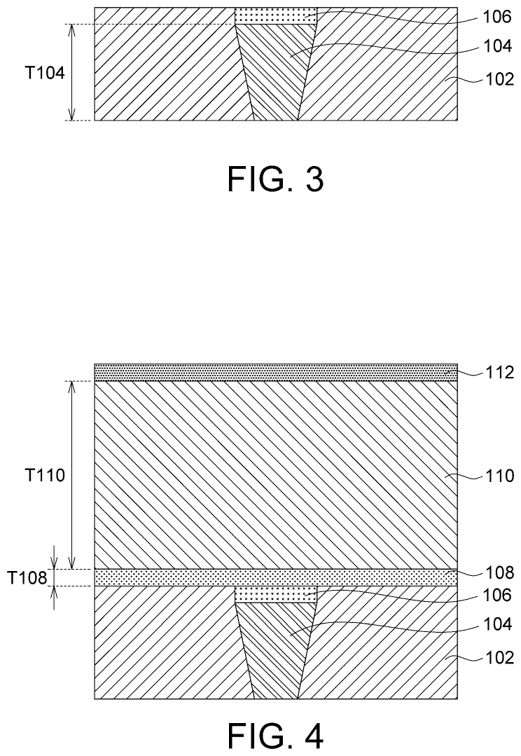

Please refer to FIGS. 2A to 2B and 3 to 13. FIGS. 2A to 2B show a flowchart of a manufacturing method of the semiconductor structure 100 according to one embodiment of the present disclosure. FIGS. 3 to 13 illustrate steps in the manufacturing method described in the FIGS. 2A to 2B. In step S104, as shown in the FIG. 3, the contact layer 104 is formed in a dielectric layer 102. The material of the contact layer 104 could be one of the following elements or their alloys, like Cu, Co, Ru, Mo, Cr, W, Mn, Rh, Ir, Ni, Pd, Pt, Ag, Au, Al. The thickness T104 of the contact layer 104 could be 50 Å to 500 Å. The contact layer 104 could be formed by PVD, CVD, ALD process.

Then, in step S106, as shown in the FIG. 3, a capping layer 106 is formed on the contact layer 104.

Next, in step S108, as shown in the FIG. 4, a glue layer 108 is formed on the dielectric layer 102 and the capping layer 106. The material of the glue layer 108 could be composed of Ta, Ti or other metal nitride. The glue layer 108 could provide good adhesion to the metal layer 110 and the capping layer 106. The thickness T108 of the glue layer 108 ranges from 2 Å to 100 Å. The glue layer 108 could be formed by PVD, CVD, ALD processes.

Afterwards, in step S110, as shown in the FIG. 4, the metal layer 110 is formed on the glue layer 108. The material of the metal layer 110 could be one of the following elements or their alloys, like Cu, Co, Ru, Mo, Cr, W, Mn, Rh, Ir, Ni, Pd, Pt, Ag, Au, Al. The thickness T110 of the metal layer 110 could be 50 Å to 500 Å. The metal layer 110 could be formed by PVD, CVD, ALD process.

Then, in step S112, as shown in the FIG. 4, a hard mask 112 is formed on the metal layer 110.

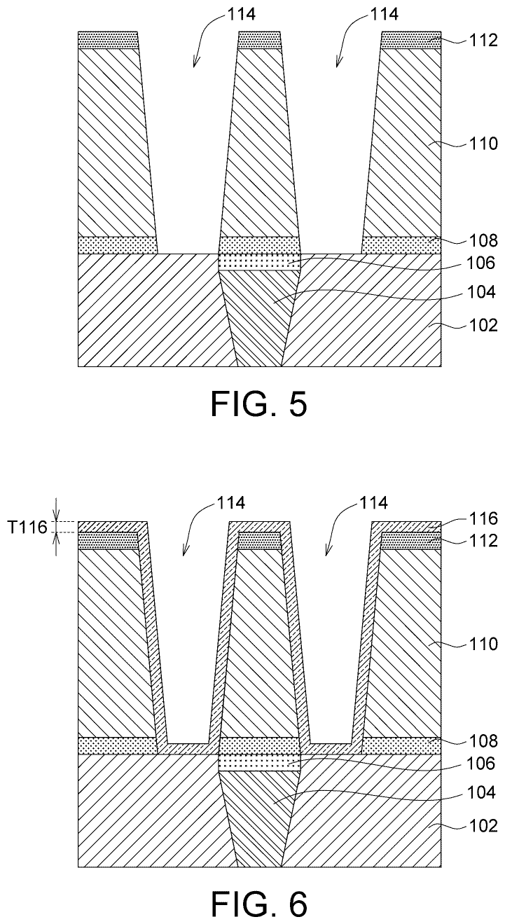

Next, in step S113, as shown in the FIG. 5, the hard mask 112 is patterned.

Then, in step S114, as shown in the FIG. 5, the metal layer 110 and the glue layer 108 are etched to form the at least one concave 114.

Afterwards, in step S116, as shown in the FIG. 6, a dielectric capping layer 116 is formed on a bottom and a lateral wall of the concave 114. The material of the dielectric capping layer 116 could be SiO, SiCO, SiNO, SiCN, SiCON, AlN, AION, AlO or a combination thereof. The dielectric capping layer 116 could provide good adhesion to the metal layer 110 and the metal-organic framework layer 120. Thickness T116 of the dielectric capping layer 116 ranges from 2 Å to 50 Å. The dielectric capping layer 116 could be performed by PVD, CVD, ALD, PECVD, PEALD process.

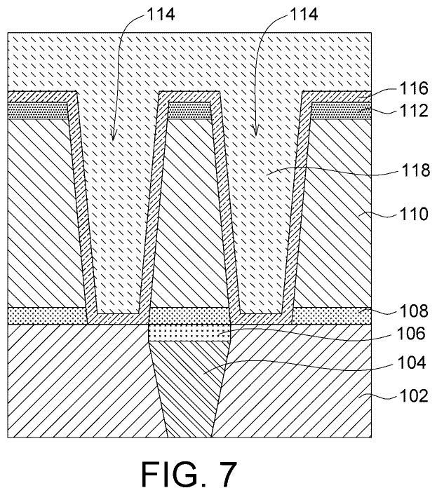

Next, in step S118, as shown in the FIG. 7, a sacrificial layer 118 is formed in the concave 114. The material of the sacrificial layer 118 is an organic material including C, O, N or H.

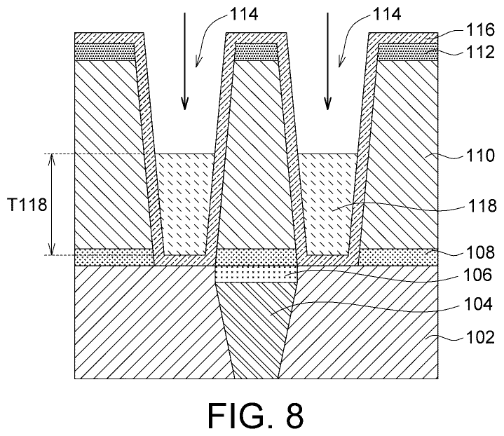

Then, in step S119, as shown in the FIG. 8, the sacrificial layer 118 is recessed. After recessing, the sacrificial layer 120 occupies 30% to 60% of the concave 114. For example, a thickness T118 of the sacrificial layer 118 is 10 Å to 100 Å.

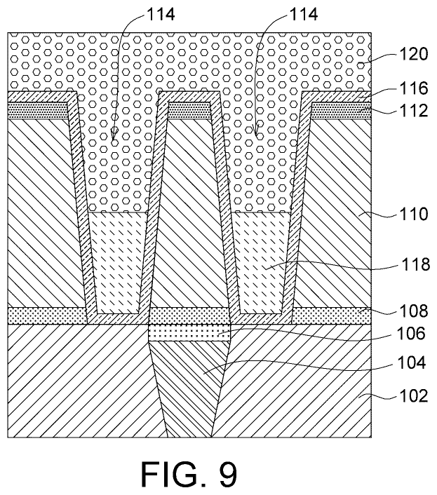

Next, in step S120, as shown in the FIG. 9, the metal-organic framework layer 120 is filled in the concave 114. The material of the metal-organic framework layer 120 could be Zn, Sr, Pb, Mn, Co or Pb based organic network crystal. In this step, the metal-organic framework layer 120 could be formed by CVD, ALD, MLD, or spin-on processes. The metal-organic framework layer 120 could provide good adhesion to the dielectric capping layer 116.

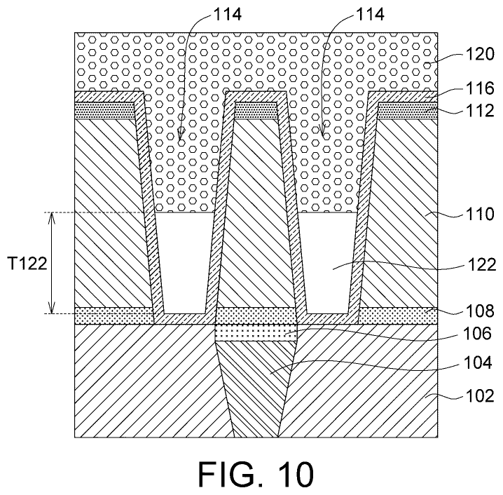

Then, in step S122, as shown in the FIG. 10, the sacrificial layer 118 is removed to form the air gap 122 in the concave 114. In one embodiment, the sacrificial layer 118 could be removed by a thermal baking process at 100 to 300° C. for 2 to 3 minutes. Or, in another embodiment, the sacrificial layer 118 could be removed by a UV curing process. After removing the sacrificial layer 118, the sacrificial layer 118 is replaced by the air gap 122. The air gap 122 occupies 30% to 60% of the concave 114. For example, the thickness T122 of the air gap 122 is 10 Å to 100 Å.

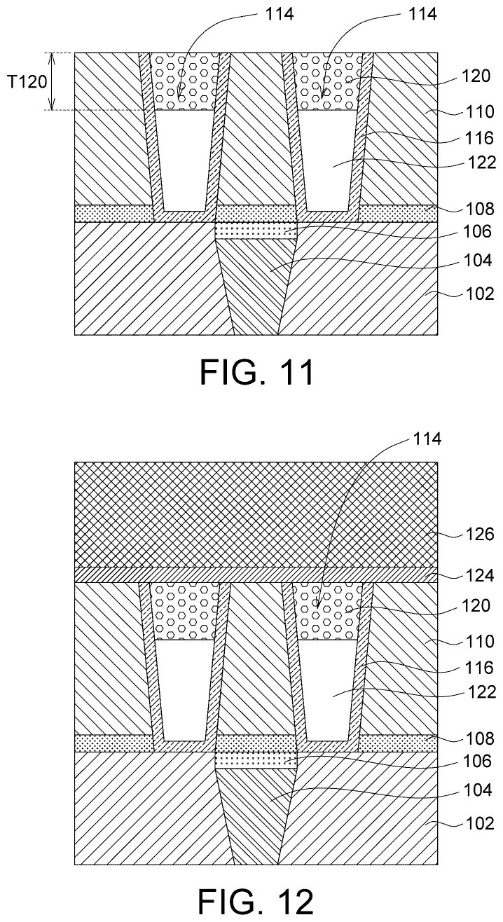

Afterwards, in step S123, as shown in the FIG. 11, the metal-organic framework layer 120 and the metal layer 110 are polished. After polishing, the metal-organic framework layer 120 occupies 20% to 50% of the concave 114 and the air gap 122 occupies 50% to 80% of the concave 114. For example, the thickness T120 of the metal-organic framework layer 120 could be 50 Å to 700 Å.

Next, in step S124, as shown in the FIG. 12, an etching stop layer 124 is formed on the metal-organic framework layer 120 and the metal layer 110.

Then, in step S126, as shown in the FIG. 12, a low-k material layer 126 is formed on the etching stop layer 124.

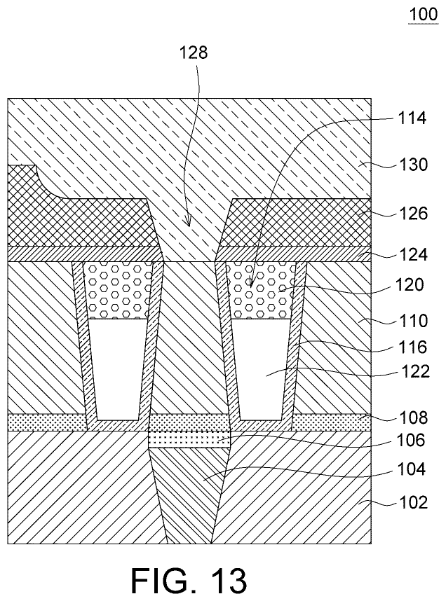

Next, in step S128, as shown in the FIG. 13, the low-k material layer 126 is patterned to forming at least one opening 128 exposing part of the metal layer 110.

Then, in step S130, as shown in the FIG. 13, the conductive layer 130 is formed in the opening 128 to connect to the metal layer 110. The material of the conductive layer 130 could be one of the following elements or their alloys, like Cu, Co, Ru, Mo, Cr, W, Mn, Rh, Ir, Ni, Pd, Pt, Ag, Au, Al. The thickness T110 of the conductive layer 130 could be 50 Å to 500 Å. The conductive layer 130 could be formed by PVD, CVD, ALD process.

As shown in the FIG. 13, in the semiconductor structure 100, the contact layer 104, the metal layer 110 and the conductive layer 130 are stacked and electrically connected. The metal-organic framework layer 120 and the air gap 122 are formed in the concave 114 to reduce the capacitance.

The air gap 122 is formed after etching the metal layer 110. This kind of metal first process could avoid low-k material damage induced by the etching process in traditional damascene scheme. And the controllable air gap 122 could give extremely low capacitance benefit.

The metal-organic framework layer 120 is possible to give ultra-low K values with low leakage current and keeps good thermal/mechanical properties than other low-density amorphous SiOC or organic polymer.

Based on above, a novel metal etching scheme is provided with air gap 122 as low-C interconnect. The novel scheme with the metal-organic framework layer 120 as gap-filled dielectric for better mechanical and thermal conductive properties.

The semiconductor structure and the manufacturing method in the present disclosure give several advantages. For example, the metal layer 110 and dielectric integrity is kept. The metal or dielectric damage & resistance and capacitance penalty could be prevented. The capacitance penalty from air gap 122 and the dielectric capping layer 116 is lowered. No resistance penalty is resulted from the high resistance material of the glue layer 108 (TaN or TiN). the metal-organic framework layer 120 above the air gap 122 results better mechanical tolerance and good thermal dissipation.

According to one example embodiment, a manufacturing method of a semiconductor structure is provided. The manufacturing method of the semiconductor structure includes: forming a sacrificial layer in a concave in a metal layer; recessing the sacrificial layer; filling a metal-organic framework layer in the concave; and removing the sacrificial layer to form an air gap in the concave.

Based on the manufacturing method of the semiconductor structure described in the previous embodiments, the sacrificial layer 118 is removed by a thermal baking process.

Based on the manufacturing method of the semiconductor structure described in the previous embodiments, the sacrificial layer is removed by a UV curing process.

Based on the manufacturing method of the semiconductor structure described in the previous embodiments, a material of the metal-organic framework layer is Zn, Sr, Pb, Mn, Co or Pb based organic network crystal.

Based on the manufacturing method of the semiconductor structure described in the previous embodiments, a material of the sacrificial layer 118 is an organic material including C, O, N or H.

Based on the manufacturing method of the semiconductor structure described in the previous embodiments, after recessing, a thickness of the sacrificial layer is 10 Å to 100 Å.

Based on the manufacturing method of the semiconductor structure described in the previous embodiments, a thickness of the metal-organic framework layer is 50 Å to 700 Å.

Based on the manufacturing method of the semiconductor structure described in the previous embodiments, after recessing, the sacrificial layer occupies 50% to 80% of the concave.

Based on the manufacturing method of the semiconductor structure described in the previous embodiments, the metal-organic framework layer occupies 20% to 50% of the concave.

According to one example embodiment, a semiconductor structure is provided. The semiconductor structure includes a metal layer, a metal-organic framework layer and an air gap. The metal layer has a concave. The metal-organic framework layer is disposed in the concave. The air gap is located in the concave. The air gap is located between the metal-organic framework layer and a bottom of the concave.

Based on the semiconductor structure described in the previous embodiments, a material of the metal-organic framework layer is Zn, Sr, Pb, Mn, Co or Pb based organic network crystal.

Based on the semiconductor structure described in the previous embodiments, a material of the sacrificial layer is an organic material including C, O, N or H.

Based on the semiconductor structure described in the previous embodiments, a thickness of the air gap is 10 Å to 100 Å.

Based on the semiconductor structure described in the previous embodiments, a thickness of the metal-organic framework layer is 50 Å to 700 Å.

Based on the semiconductor structure described in the previous embodiments, the air gap occupies 50% to 80% of the concave.

Based on the semiconductor structure described in the previous embodiments, the metal-organic framework layer occupies 20% to 50% of the concave.

According to one example embodiment, a manufacturing method of a semiconductor structure is provided. The manufacturing method of the semiconductor structure includes: forming a contact layer in a dielectric layer; forming a capping layer on the contact layer; forming a glue layer on the dielectric layer and the capping layer; forming a metal layer on the glue layer; forming a hard mask on the metal layer; patterning the hard mask; etching the metal layer and the glue layer to form at least one concave; forming a dielectric capping layer on a bottom and a lateral wall of the concave; forming a sacrificial layer in the concave; recessing the sacrificial layer; filling a metal-organic framework layer in the concave; removing the sacrificial layer to form an air gap in the concave; polishing the metal-organic framework layer and the metal layer; forming an etching stop layer on the metal-organic framework layer and the metal layer; forming a low-k material layer on the etching stop layer; patterning the low-k material layer to forming at least one opening exposing part of the metal layer; and forming a conductive layer in the opening to connect to the metal layer.

Based on the manufacturing method of the semiconductor structure described in the previous embodiments, the sacrificial layer is removed by a thermal baking process.

Based on the manufacturing method of the semiconductor structure described in the previous embodiments, the sacrificial layer is removed by a UV curing process.

Based on the manufacturing method of the semiconductor structure described in the previous embodiments, the metal-organic framework layer occupies 20% to 50% of the concave.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A manufacturing method of a semiconductor structure, comprising:
forming a sacrificial layer in a concave in a metal layer;
recessing the sacrificial layer;
filling a metal-organic framework layer in the concave; and
removing the sacrificial layer to form an air gap in the concave.

2. The manufacturing method of the semiconductor structure according to claim 1, wherein the sacrificial layer is removed by a thermal baking process.

3. The manufacturing method of the semiconductor structure according to claim 1, wherein the sacrificial layer is removed by a UV curing process.

4. The manufacturing method of the semiconductor structure according to claim 1, wherein a material of the metal-organic framework layer is Zn, Sr, Pb, Mn, Co or Pb based organic network crystal.

5. The manufacturing method of the semiconductor structure according to claim 1, wherein a material of the sacrificial layer is an organic material including C, O, N or H.

6. The manufacturing method of the semiconductor structure according to claim 1, wherein after recessing, a thickness of the sacrificial layer is 10 Å to 100 Å.

7. The manufacturing method of the semiconductor structure according to claim 1, wherein a thickness of the metal-organic framework layer is 50 Å to 700 Å.

8. The manufacturing method of the semiconductor structure according to claim 1, wherein after recessing, the sacrificial layer occupies 50% to 80% of the concave.

9. The manufacturing method of the semiconductor structure according to claim 1, wherein the metal-organic framework layer occupies 20% to 50% of the concave.

10. A semiconductor structure, comprising:
a metal layer, having a concave;
a metal-organic framework layer, disposed in the concave; and
an air gap, located in the concave, wherein the air gap is located between the metal-organic framework layer and a bottom of the concave.

11. The semiconductor structure according to claim 10, wherein a material of the metal-organic framework layer is Zn, Sr, Pb, Mn, Co or Pb based organic network crystal.

12. The semiconductor structure according to claim 10, wherein a material of the sacrificial layer is an organic material including C, O, N or H.

13. The semiconductor structure according to claim 10, wherein a thickness of the air gap is 10 Å to 100 Å.

14. The semiconductor structure according to claim 10, wherein a thickness of the metal-organic framework layer is 50 Å to 700 Å.

15. The semiconductor structure according to claim 10, wherein the air gap occupies 50% to 80% of the concave.

16. The semiconductor structure according to claim 10, wherein the metal-organic framework layer occupies 20% to 50% of the concave.

17. A manufacturing method of a semiconductor structure, comprising:
forming a contact layer in a dielectric layer;
forming a capping layer on the contact layer;
forming a glue layer on the dielectric layer and the capping layer;
forming a metal layer on the glue layer;
forming a hard mask on the metal layer;
patterning the hard mask;
etching the metal layer and the glue layer to form at least one concave;
forming a dielectric capping layer on a bottom and a lateral wall of the concave;
forming a sacrificial layer in the concave;
recessing the sacrificial layer;
filling a metal-organic framework layer in the concave;
removing the sacrificial layer to form an air gap in the concave;
polishing the metal-organic framework layer and the metal layer;
forming an etching stop layer on the metal-organic framework layer and the metal layer;
forming a low-k material layer on the etching stop layer;
patterning the low-k material layer to forming at least one opening exposing part of the metal layer; and
forming a conductive layer in the opening to connect to the metal layer.

18. The manufacturing method of the semiconductor structure according to claim 17, wherein the sacrificial layer is removed by a thermal baking process.

19. The manufacturing method of the semiconductor structure according to claim 17, wherein the sacrificial layer is removed by a UV curing process.

20. The manufacturing method of the semiconductor structure according to claim 17, wherein the metal-organic framework layer occupies 20% to 50% of the concave.
